(19) United States
(12) Patent Application Publication
(10) Pub. No.: US 2023/0275031 A1
(43) Pub. Date: Aug. 31, 2023

(54) Method of Bonding Active Dies and Dummy Dies and Structures Thereof

(71) Applicant: Taiwan Semiconductor Manufacturing Co., Ltd., Hsinchu (TW)

(72) Inventors: Chih-Chia Hu, Taipei (TW); Sung-Feng Yeh, Taipei City (TW); Ming-Fa Chen, Taichung City (TW)

(21) Appl. No.: 17/661,325

(22) Filed: Apr. 29, 2022

Related U.S. Application Data
(60) Provisional application No. 63/268,521, filed on Feb. 25, 2022.

(51) Int. Cl. H01L 23/544; H01L 23/00; H01L 23/48

(52) U.S. Cl. CPC H01L 23/544; H01L 23/562; H01L 23/481; H01L 2223/54426

(57) ABSTRACT

A method includes bonding a first plurality of active dies to a second plurality of active dies in a wafer. The second plurality of active dies are in an inner region of the wafer. A first plurality of dummy dies are bonded to a second plurality of dummy dies in the wafer. The second plurality of dummy dies are in a peripheral region of the wafer, and the peripheral region encircles the inner region.

### PRIORITY CLAIM AND CROSS-REFERENCE

This application claims the benefit of the following provisionally filed U.S. patent application: Application No. 63/268,521, filed on Feb. 25, 2022, and entitled “Dummy Die at Wafer Edge for Warpage Control,” which application is hereby incorporated herein by reference.

### BACKGROUND

Packages of integrated circuits are becoming increasing complex, with more device dies packaged in the same package to achieve more functions. For example, a package structure has been developed to include a plurality of device dies such as processors and memory cubes in the same package. The package structure can include device dies formed using different technologies and have different functions bonded to the same device die, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12 illustrate the cross-sectional views of intermediate stages in a packaging process adopting dummy dies in accordance with some embodiments.

FIGS. 13 and 14 illustrate the cross-sectional views of intermediate stages in the bonding of third-tier dies in accordance with some embodiments.

FIG. 15 illustrates a top view of a wafer and the corresponding active dies and dummy dies in accordance with some embodiments.

FIG. 16 illustrates an active die and the corresponding alignment marks in accordance with some embodiments.

FIG. 17 illustrates dummy dies and the corresponding alignment marks in accordance with some embodiments.

FIG. 18 illustrates the positioning and the bonding of dummy dies using reference points and offset values in accordance with some embodiments.

FIG. 19 illustrates a whole-wafer map including the positioning of dummy dies in accordance with some embodiments.

FIGS. 20 and 21 illustrate a wafer and an active die having both of active dies and dummy dies bonded thereon in accordance with some embodiments.

FIGS. 22-25 illustrate the cross-sectional views of the bonded dies in accordance with some embodiments.

FIGS. 26 and 27 illustrate packages with electrical connectors formed on a top-tier die and a bottom-tier die, respectively, in accordance with some embodiments.

FIG. 28 illustrates a process flow of a packaging process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of bonding active dies and dummy dies, and the resulting packages are provided. In accordance with some embodiments of the present disclosure, active dies are bonded to a wafer-level package component. The positions of the active dies and the positions of bonding dummy dies are determined, and alignment marks may be formed. The dummy dies may be bonded to the peripheral regions, and may also be bonded to the inner region, of the wafer-level package component. With dummy dies being bonded to cover some parts of the wafer-level package component, the gap-fill ratio is reduced, and the warpage of the resulting reconstructed wafer is reduced. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

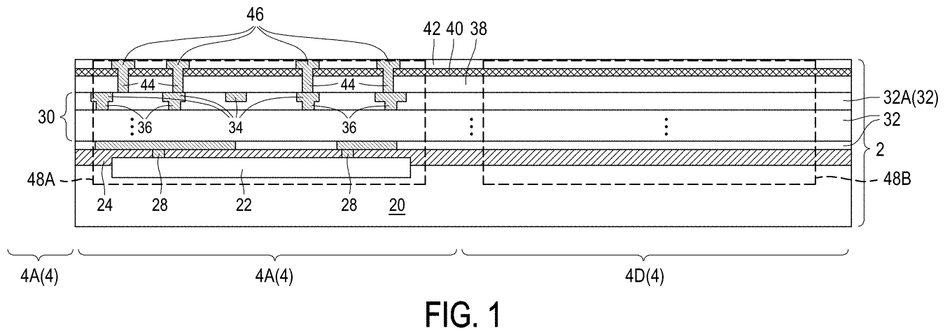

FIGS. 1 through 12 illustrate the cross-sectional views of intermediate stages in a packaging process adopting dummy dies in accordance with some embodiments of the present disclosure. The corresponding processes are also reflected schematically in the process flow 200 as shown in FIG. 23.

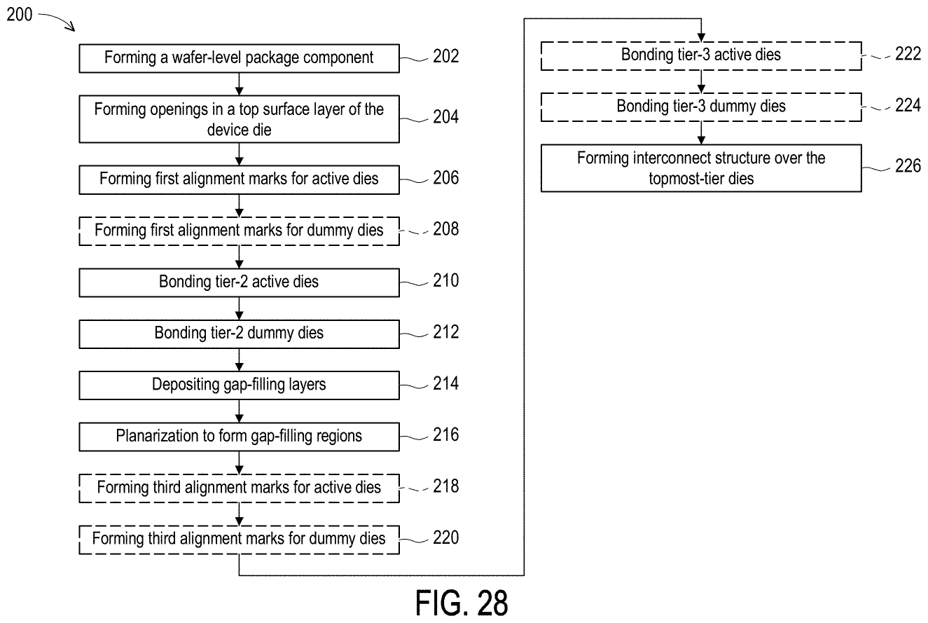

FIG. 1 illustrates the cross-sectional view in the formation of a wafer-level package component 2. The respective process is illustrated as process 202 in the process flow 200 as shown in FIG. 28. In accordance with some embodiments of the present disclosure, package component 2 is a device wafer including active devices 22 such as transistors and/or diodes, and possibly passive devices such as capacitors, inductors, resistors, or the like. Through-out the description, the dies in package component 2 are referred to as tier-1 dies or bottom-tier dies, and the corresponding tier is referred to as tier-1 or a bottom tier. Package component 2 may include a plurality of chips 4 therein, with one of chips 4 being illustrated. Chips 4 are alternatively referred to as (device) dies hereinafter. In accordance with some embodiments of the present disclosure, device dies 4 are logic dies, which may be Central Processing Unit (CPU) dies, Micro Control Unit (MCU) dies, Input-output (IO) dies, BaseBand (BB) dies, Application processor (AP) dies, or the like. Device dies 4 may also be memory dies such as Dynamic Random-Access Memory (DRAM) dies or Static Random-Access Memory (SRAM) dies.

In accordance with some embodiments of the present disclosure, package component 2 is an unsawed wafer, which includes a semiconductor substrate continuously extending throughout all dies in package component 2. In accordance with alternative embodiments, package component is a reconstructed wafer, which includes discrete device dies and an encapsulant encapsulating the discrete device dies therein. In subsequent discussion, package component 2 is referred to as wafer 2, which is illustrated using a device wafer as an example. The embodiments of the present disclosure may also be applied to other types of package components such as interposer wafers.

In accordance with some embodiments of the present disclosure, wafer 2 includes semiconductor substrate 20 and the features formed at a top surface of semiconductor substrate 20. Semiconductor substrate 20 may be formed of crystalline silicon, crystalline germanium, crystalline silicon germanium, and/or the like. Semiconductor substrate 20 may also be a bulk silicon substrate or a Silicon-On-Insulator (SOI) substrate. Shallow Trench Isolation (STI) regions (not shown) may be formed in semiconductor substrate 20 to isolate the active regions in semiconductor substrate 20. Although not shown, through-vias may be formed to extend into semiconductor substrate 20, and the through-vias are used to electrically inter-couple the features on opposite sides of wafer 2.

In accordance with some embodiments of the present disclosure, wafer 2 includes integrated circuit devices 22, which are formed on the top surface of semiconductor substrate 20. Exemplary integrated circuit devices 22 may include active devices such as Complementary Metal-Oxide Semiconductor (CMOS) transistors and diodes, and passive devices such as resistors, capacitors, diodes, and/or the like. The details of integrated circuit devices 22 are not illustrated herein. In accordance with alternative embodiments, wafer 2 is used for forming interposers, in which substrate 20 may be a semiconductor substrate or a dielectric substrate.

Inter-Layer Dielectric (ILD) 24 is formed over semiconductor substrate 20, and fills the space between the gate stacks of transistors (not shown) in integrated circuit devices 22. In accordance with some embodiments, ILD 24 is formed of Phospho Silicate Glass (PSG), Boro Silicate Glass (BSG), Boron-Doped Phospho Silicate Glass (BPSG), Fluorine-Doped Silicate Glass (FSG), silicon oxide, or the like. ILD 24 may be formed using spin coating, Flowable Chemical Vapor Deposition (FCVD), Chemical Vapor Deposition (CVD), Plasma Enhanced Chemical Vapor Deposition (PECVD), Low Pressure Chemical Vapor Deposition (LPCVD), or the like.

Contact plugs 28 are formed in ILD 24, and are used to electrically connect integrated circuit devices 22 to overlying metal lines 34 and vias 36. In accordance with some embodiments of the present disclosure, contact plugs 28 are formed of a conductive material selected from tungsten, aluminum, copper, titanium, tantalum, titanium nitride, tantalum nitride, alloys therefore, and/or multi-layers thereof. The formation of contact plugs 28 may include forming contact openings in ILD 24, filling a conductive material(s) into the contact openings, and performing a planarization (such as a Chemical Mechanical Polish (CMP) process) to level the top surfaces of contact plugs 28 with the top surface of ILD 24.

Interconnect structure 30 is formed over ILD 24 and contact plugs 28. Interconnect structure 30 includes dielectric layers 32, and metal lines 34 and vias 36 formed in dielectric layers 32. Dielectric layers 32 are alternatively referred to as Inter-Metal Dielectric (IMD) layers 32 hereinafter. In accordance with some embodiments of the present disclosure, at least the lower ones of dielectric layers 32 are formed of a low-k dielectric material having a dielectric constant (k-value) lower than about 3.0 or about 2.5. Dielectric layers 32 may be formed of or comprises a carbon-containing low-k dielectric material, Hydrogen SilsesQuioxane (HSQ), MethylSilsesQuioxane (MSQ), or the like. In accordance with alternative embodiments of the present disclosure, some or all of dielectric layers 32 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, or the like, are formed between IMD layers 32, and are not shown for simplicity.

Metal lines 34 and vias 36 are formed in dielectric layers 32. The metal lines 34 at a same level are collectively referred to as a metal layer hereinafter. In accordance with some embodiments of the present disclosure, interconnect structure 30 includes a plurality of metal layers that are interconnected through vias 36. Metal lines 34 and vias 36 may be formed of copper or copper alloys, and they can also be formed of other metals. The formation process may include single damascene and dual damascene processes.

Metal lines 34 include some metal lines in top dielectric layer 32, which metal lines are referred to as top metal lines. The top metal lines 34 are also collectively referred to as being a top metal layer. The respective dielectric layer 32A may be formed of a non-low-k dielectric material such as Un-doped Silicate Glass (USG), silicon oxide, silicon nitride, or the like. Dielectric layer 32A may also be formed of a low-k dielectric material, which may be selected from the similar materials of the underlying IMD layers 32.

In accordance with some embodiments of the present disclosure, dielectric layers 38, 40, and 42 are formed over the top metal layer. Dielectric layers 38 and 42 may be formed of silicon-containing dielectric materials such as silicon oxide, silicon oxynitride, silicon oxy-carbide, or the like, Dielectric layer 40 may be formed of a dielectric material different from the dielectric material of dielectric layer 42. For example, dielectric layer 40 may be formed of silicon nitride, silicon carbide, or the like. In accordance with alternative embodiments, instead of forming three dielectric layers 38, 40, and 42, a single dielectric layer or two dielectric layers may be formed.

Bond pads 46 and vias 44 are formed in dielectric layers 42, 40, and 38. In accordance with some embodiments, bond pads 46 and vias 44 are formed as dual damascene structures using dual damascene processes, with each of the dual damascene structure including a diffusion barrier layer and a metallic material on the diffusion barrier layer. The diffusion barrier layer may be formed of or comprise titanium, titanium nitride, tantalum, tantalum nitride, or the like. The metallic material may be formed of or comprise copper or a copper alloy. The top surfaces of bond pads 46 may be coplanar with the top surface of dielectric layer 42, which are formed due to the planarization process such as a Chemical Mechanical Polish (CMP) process.

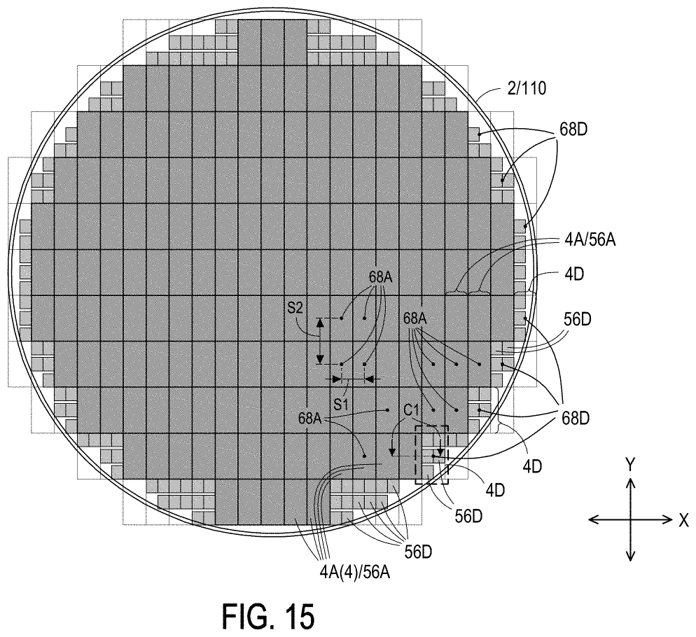

FIG. 1 illustrates an active die 4A and a dummy die 4D. A top view of the structure shown in FIG. 1 is shown in FIG. 15, wherein the cross-sectional view may be obtained from the cross-section C1-C1 in FIG. 15. Wafer 2 includes edge (peripheral) regions, in which dummy dies 4D are located. Active dies 4A are full dies having rectangular top-view shapes, and have full electrical functions. Dummy dies 4D are partial rectangular dies since wafer 2 has a round top view, and hence a part of each of the dummy dies 4D is cut due to the curved wafer edge. FIG. 15 also illustrates the missing portions of the partial dies to show what the dies would look like if they are not partial. Dummy dies 4D may not function normally since they either include only parts of electrical devices in a full-functional device die, or don't have any electrical devices. Active dies 4A are in an inner region of wafer 2, and are encircled by the dummy dies 4D in the peripheral region of wafer 2.

Referring back to FIG. 1, in accordance with some embodiments, depending on the formation process of wafer 2, region 48B are free from active devices, metal lines, vias, and the like, which are formed in region 48A in active die 4A. In accordance with alternative embodiments, the region 48B in dummy die 4D includes some circuits, metal lines etc., which are formed simultaneously as the corresponding features in region 48A in active die 4A. The circuits in region 48B, however, are less than the circuits in region 48A. In accordance with yet alternative embodiments, the regions 48B of some of dummy dies 4D include circuits therein, while the regions 48B of some other dummy dies 4D do not include circuits therein.

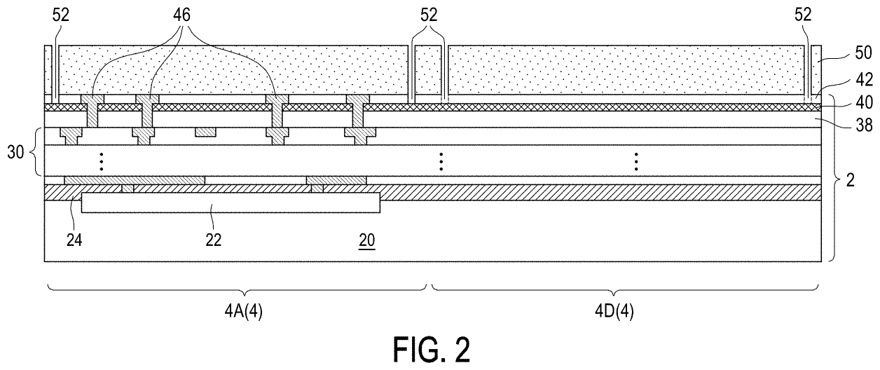

Referring to FIG. 2, etching mask 50 is formed and patterned. Etching mask 50 may include a photoresist, and may be a single-layer etching mask, a tri-layer etching mask, or the like. The patterned etching mask 50 is then used to etch the underlying dielectric layer 42, so that openings 52 are formed in dielectric layer 42. The respective process is illustrated as process 204 in the process flow 200 as shown in FIG. 28. In accordance with some embodiments, the etching process stops on the top surface of etch stop layer 40. In accordance with alternative embodiments, openings 52 may extend into etch stop layer 40, and may or may not extend into dielectric layer 38. In accordance with yet alternative embodiments, openings 52 are formed to extend partially into dielectric layer 42. After the etching process, etching mask 50 is removed.

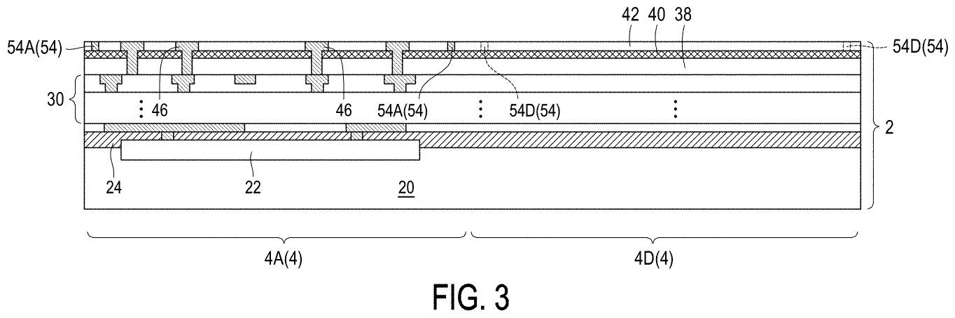

FIG. 3 illustrates the formation of alignment marks 54A used for aligning active dies. Accordingly, alignment marks 54A are referred to as active alignment marks. The respective process is illustrated as process 206 in the process flow 200 as shown in FIG. 28. In accordance with some embodiments, alignment marks 54D may be (or may not be) formed, and are illustrated using dashed lines. The respective process is illustrated as process 208 in the process flow 200 as shown in FIG. 28. Alignment marks 54D are used for aligning dummy dies, and are accordingly referred to as dummy alignment marks. Active alignment marks 54A and dummy alignment marks 54D (if formed) may be formed in the same formation process or separate formation processes. Active alignment marks 54A and dummy alignment marks 54D are collectively referred to as alignment marks 54 hereinafter.

In accordance with some embodiments, alignment marks 54 are formed of or comprise a metal, a metal alloy, a metal compound, etc., to increase the contrast of alignment marks 54 relative to the surrounding materials. For example, alignment marks 54 may be formed of or comprise copper, a copper alloy, tungsten, nickel, and or the like. Each of alignment marks 54 includes a metal region, and may or may not include an adhesion layer underlying and lining the metal region. The adhesion layer may be formed of or comprise titanium, titanium nitride, tantalum, tantalum nitride, or the like. The formation process may include depositing the adhesion layer (if formed) as a conformal layer, for example using Physical Vapor Deposition (PVD), and depositing a metallic material over the adhesion region. The metallic material may be formed through a plating process such as an Electro-Chemical Plating (ECP) process. A planarization process such as a CMP process is then performed to remove excess portions of the adhesion layer and the metallic material, leaving alignment marks 54.

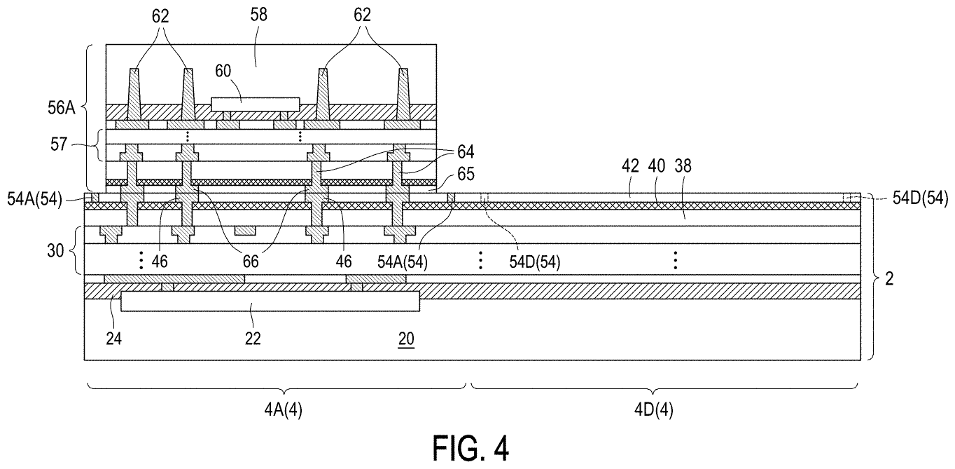

FIG. 4 illustrates the bonding of (tier-2) active dies 56A to the respective (tier-1) dies 4A. The respective process is illustrated as process 210 in the process flow 200 as shown in FIG. 28. In accordance with some embodiments, active dies 56A are logic dies (which may be CPU dies), IO dies, Base-Band dies, or AP dies. Active dies 56A may also be memory dies. One active die 56A may include semiconductor substrate 58, which may be a silicon substrate, and integrated circuits 60 (which may include active devices such as transistors and passive devices). Through-Silicon Vias (TSVs) 62, sometimes referred to as through-semiconductor vias or through-vias, are formed to extend into semiconductor substrate 58. Also, an active die 56A may include an interconnect structure 57 for connecting to the active devices and passive devices in device dies 56A. The interconnect structure 57 includes metal lines and vias (not shown).

Active die 56A include bond pads 66 and vias 64, and surface dielectric layer 65. Through-out the description, the dies bonded directly to the tier-1 dies are referred to as tier-2 dies, and the corresponding tier is referred to as tier-2 or a second tier. The structures and the materials of bond pads 66 and vias 64 may be similar to the corresponding bond pads 46 and vias 44, respectively. In accordance with some embodiments, the bonding is performed through hybrid bonding, with bond pads 66 being bonded to the respective bond pads 46 through direct metal-to-metal bonding, and dielectric layers 65 being bonded to the respective dielectric layers 42 through fusion bonding, with Si—O—Si bonds being generated.

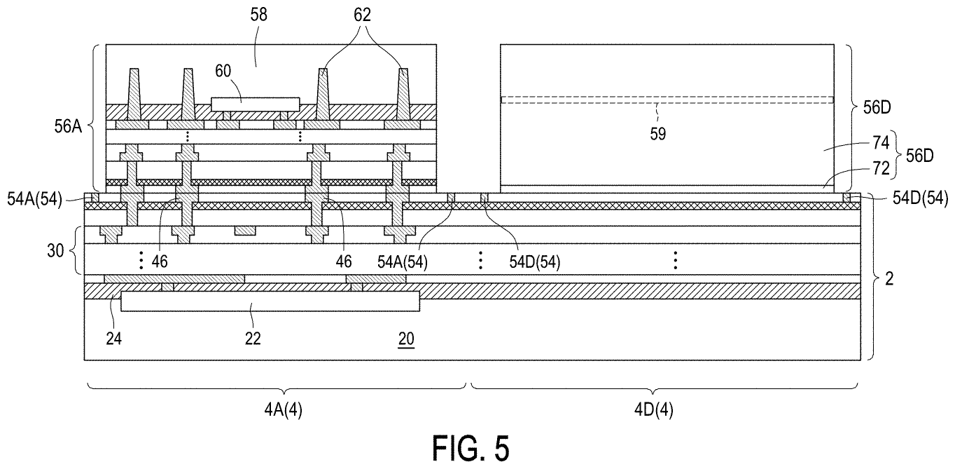

Referring to FIG. 15, a plurality of active dies 56A are bonded to the respective active dies 4A. In accordance with some embodiments, each of active die 4A may have one or a plurality of active dies 56A bonded thereon, and vice versa. During the bonding of the plurality of active dies 56A, the bonding tool (not shown) picks-and-places a first active die 56A, aligns the first active die 56A to the respective active die 4A using active alignment marks 54A (FIG. 4), and pre-bonds the first active die 56A to the respective active die 4A. The alignment is performed using an optical device, which may include a camera, so that the alignment marks 54A can be found. After the pre-bonding of the first active die 56A, the bonding tool picks-and-places a second active die 56A, aligns the second active die 56A to the respective active die 4A using active alignment marks 54A, and pre-bonds the second active die 56A to the respective active die 4A. This process may be repeated until all of the active dies 56A are bonded. An annealing process may then be performed to permanently bond active dies 56A to the corresponding active dies 4A. In accordance with alternative embodiments, the annealing process is performed after pre-bonding dummy dies 56D (FIG. 5), so that the active dies 56A and dummy dies 56D are permanently bonded in a same annealing process.

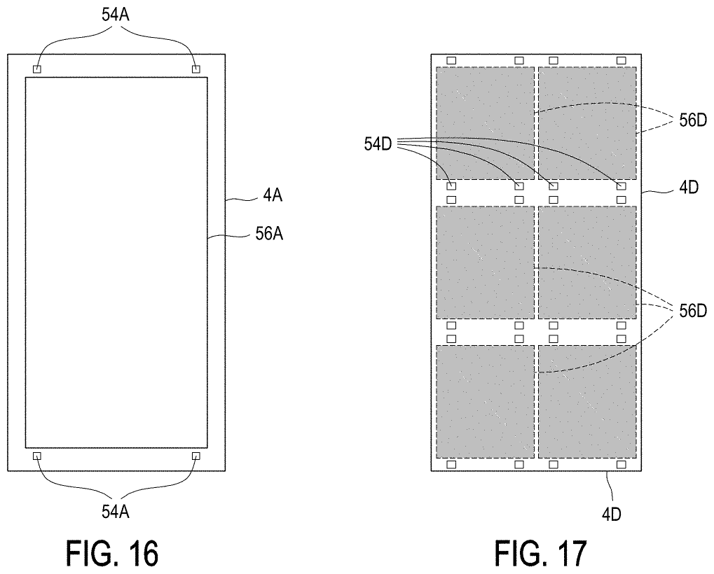

FIG. 16 illustrates a top view of active alignment marks 54A and the respective active dies 4A and 56A. In accordance with some embodiments, active alignment marks 54A are formed close to the corners of the respective active die 4A (FIG. 4), and define the region of the active die 4A for placing active die 56A thereon.

FIG. 5 illustrates the bonding of (tier-2) dummy dies 56D to (tier-1) dummy dies 4D. The respective process is illustrated as process 212 in the process flow 200 as shown in FIG. 28. Referring to FIG. 15, dummy dies 56D are bonded to the peripheral regions of wafer 2. In accordance with some embodiments, since dummy dies 4D have different shapes and/or different sizes, dummy dies 56D are smaller than the respective dummy dies 4D, and a dummy die 4D may fit a plurality of dummy dies 56D thereon. Also, different dummy dies 4D may have different numbers of dummy dies 56D bonded thereon, depending on the shape and the sizes of dummy dies 56D.

As discussed in preceding paragraphs, the bonding of each of active dies 56A includes an alignment process, in which the respective active alignment marks 54A are identified. A reference point 68A (FIG. 15) thus may be selected for each of active dies 4A. In the following discussed example embodiments, the reference points 68A are the centers of the active dies. In accordance with alternative embodiments, the reference points may be selected as any corner (such as the top left corner or another corner) or any other corresponding points of active dies 4A. In accordance with yet alternative embodiments, the reference points 68A may be selected as being the active alignment marks 54A.

FIG. 15 illustrates a plurality of example reference points 68A. With the reference points 68A of active dies 4A being identified, the bonding tool knows the stepping window, which includes the distances S1 and S2 between two neighboring reference points 68A. Accordingly, reference points 68D of dummy dies 4D can be determined. Reference points 68D are determined by stepping away from the reference points 68A of edge-most active dies 4A for distance S1 (in the X-direction) and/or distance S2 (in the Y-direction). Accordingly, in accordance with some embodiments, the positions of dummy dies 4D are identified without forming alignment marks 54D (FIG. 5) on dummy dies 4D.

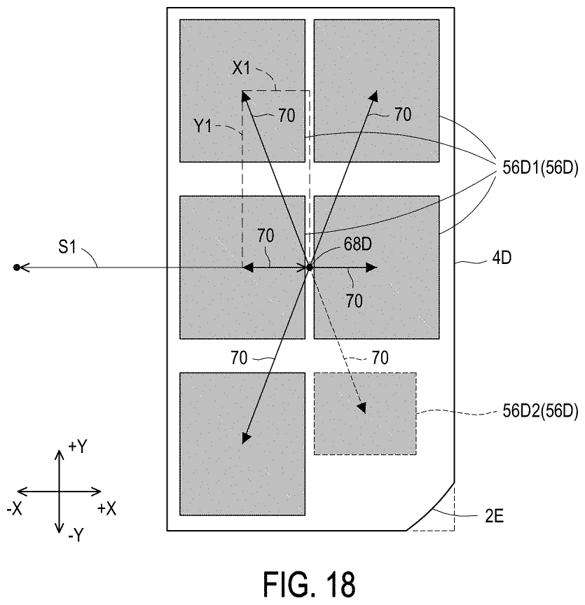

FIG. 18 illustrates the positioning process to determine the positions of dummy dies 56D, and bonding dummy dies 56D to dummy die 4D without the forming and using of dummy alignment marks. Dummy dies 56D have sizes smaller than the sizes of dummy dies 4D and active dies 4A. As discussed in the preceding paragraphs, reference point 68D has been determined, which may be the center point of dummy die 4D in accordance with an example embodiment. The bonding tool also has the knowledge of stepping windows S1 and S2, and hence can also determine the sizes and the boundaries of dummy die 4D. Also, the bonding tool may also find the edge 2E (FIG. 18) of wafer 2, and hence may determine what is the available region (for placing dummy dies 56D) of the corresponding dummy die 4D. Accordingly, the bonding tool may determine how many dummy dies 56D can fit into the available region of dummy die 4D, and determine the positions of dummy dies 56D. For example, in the illustrated example, five dummy dies may fit into the dummy die 4D.

In accordance with some embodiments, the bonding tool determines the offset values from reference point 68D to determine where to place the corresponding dummy dies 56D, and then place the dummy dies 56D to the corresponding positions. The offset values are shown with arrows 70. For example, the top left dummy die 56D is placed to a position offset from reference point 68D in the −X direction for distance X1, and in the +Y direction for distance Y1. In accordance with some embodiments, the dummy dies 56D have the same sizes. In accordance with alternative embodiments, dummy dies 56D may have two, three, or more different sizes, so that more areas of the dummy dies 4D may be covered by dummy dies 56D. For example, dummy die 56D2 may be smaller than dummy dies 56D1.

Referring back to FIG. 5, in accordance with some embodiments, dummy die 56D includes a silicon-containing dielectric layer 72, and substrate 74 bonded to silicon-containing dielectric layer 72. Silicon-containing dielectric layer 72 may be formed of or comprises SiO₂, SiN, SiC, SiCN, SiON, SiOCN, or the like, or combinations thereof. Substrate 74 may be a silicon substrate, or may comprise silicon germanium in accordance with some embodiments. Silicon-containing dielectric layer 72 may be formed of a homogeneous material, and is free from metal lines and pads formed therein. The entire substrate 74 may also be formed of a homogeneous material such as silicon (doped or undoped), and do not have any devices, metal lines, etc. therein. In accordance with alternative embodiments, the entire dummy die 56D is formed of a homogeneous material such as silicon (doped or undoped), and do not have any devices, metal lines, etc. therein.

As a result of the bonding of dummy dies 56D, as shown in FIG. 15, the coverage of dies (including active dies 56A and dummy dies 56D) is increased to be higher than when only active dies 56A are bonded. In accordance with some embodiments, the coverage may be increased by a percentage in the range between about 5 percent and about 15 percent, depending on the size of wafer 2 and the sizes of the active dies 4A and 56A and dummy dies 4D and 56D.

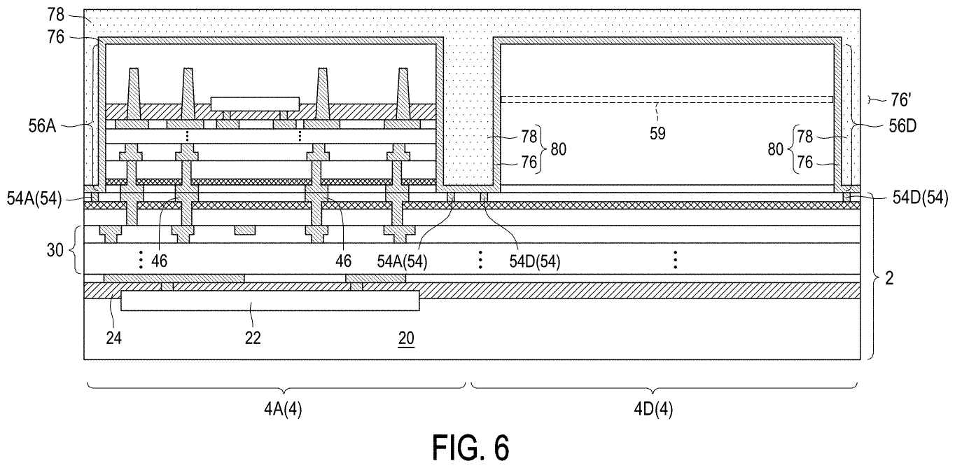

FIG. 6 illustrates the formation of gap-filling layers, which may include etch stop layer 76 and the overlying dielectric layer 78. The respective process is illustrated as process 214 in the process flow 200 as shown in FIG. 28. Etch stop layer 76 may be formed of a dielectric material that has a good adhesion to wafer 2, active dies 56A, and dummy dies 56D. In accordance with some embodiments, etch stop layer 76 is formed of or comprises a nitride-containing material such as silicon nitride. Etch stop layer 76 may be a conformal layer, with the horizontal thickness of horizontal portions and the vertical thickness of the vertical portions being substantially equal to each other, for example, with a variation smaller than about 20 percent, or smaller than about 10 percent. The deposition may include a conformal deposition method such as ALD, CVD, or the like.

Dielectric layer 78 may be formed of a material different from the material of etch stop layer 76. In accordance with some embodiments of the present disclosure, dielectric layer 78 is formed of silicon oxide, while other dielectric materials such as silicon carbide, silicon oxynitride, silicon oxy-carbo-nitride, PSG, BSG, BPSG, or the like may also be used. Dielectric layer 78 may be formed using CVD, High-Density Plasma Chemical Vapor Deposition (HDPCVD), Flowable CVD, spin-on coating, or the like. Dielectric layer 78 fully fills the remaining gaps between active dies 56A and dummy dies 56D.

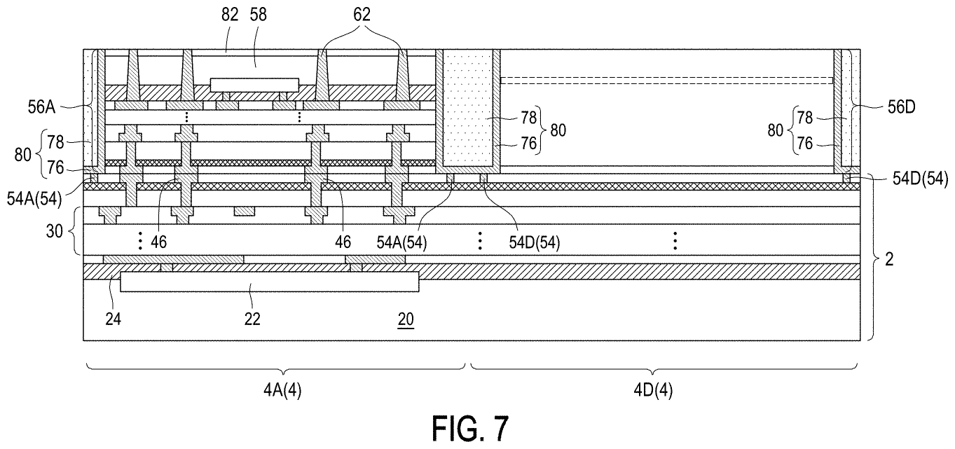

Referring to FIG. 7, a planarization process such as a CMP process or a mechanical grinding process is performed to remove excess portions of gap-filling layers 76 and 78, so that active dies 56A are exposed. The respective process is illustrated as process 216 in the process flow 200 as shown in FIG. 28. Also, through-vias 62 are exposed. The remaining portions of layers 76 and 78 are collectively referred to as (gap-filling) gap-filling dielectric regions 80.

In accordance with some embodiments, after the planarization process, dummy die 56D is exposed. In accordance with alternative embodiments, after the planarization process, dummy die 56D is buried in gap-filling dielectric regions 80. Line 59 in FIGS. 5 and 6 schematically illustrate the top surface of the buried dummy die 56D in accordance with some embodiments. Also, layer 76′ is also shown using dashed lines to represent a portion of etch stop layer 76 when dummy die 56D is buried.

With the using of dummy dies 56D, the total area of gap-filling dielectric regions 80 is reduced. The ratio of the total top-view area of gap-filling dielectric regions 80 to the total top-view area of wafer 2 is referred to as gap-fill ratio. The using of dummy dies 56D thus reduces the gap-fill ratio. Since dummy dies 56D have a Coefficient of Thermal Expansion (CTE) close to the CTE of active dies 56A, while gap-filling dielectric regions 80 have a CTE different from the CTE of active dies 56D, reducing the gap-fill ratio may reduce wafer warpage. In accordance with some embodiments, the reduction of the gap-fill ratio may be in the range between about 5 percent and about 10 percent, depending on the sizes of wafer 2, active dies 56A, and dummy dies 56D. For example, if dummy dies 56D are not used, the gap-fill ratio may be in the range between about 10 percent and about 26 percent. When dummy dies 56D are used, the gap-fill ratio may be reduced to be in the range between about 5 percent and about 20 percent.

Also, the reduction in the sizes of dummy dies 56D may result in the reduction of gap-fill ratio because more dummy dies may be used to fit the irregular sizes of dummy dies 4D. For example, sample active dies 4A may have a size of about 13 mm×26 mm, and the corresponding sample diameter of wafer 2 has a 12-inche diameter. When sample, dummy dies 56D have sizes of about 6 mm×7 mm, the gap-fill ratio is about 12.5 percent. When the sizes of sample dummy dies 56D is reduced to about 6.3 mm×4.5 mm, the gap-fill ratio is further reduced to about 11.1 percent. In accordance with some embodiments, the sizes of dummy dies 56D may be in the range between about 1 mm×1 mm and about 7 mm×7 mm.

Further referring to FIG. 7, substrate 58 may be recessed, so that through-vias 62 protrude above the back surface of substrate 58. A dielectric layer 82 is then formed on the back surface of substrate 58. The formation process includes depositing a dielectric material such as silicon oxide, and performing a planarization process until through-vias 62 are exposed.

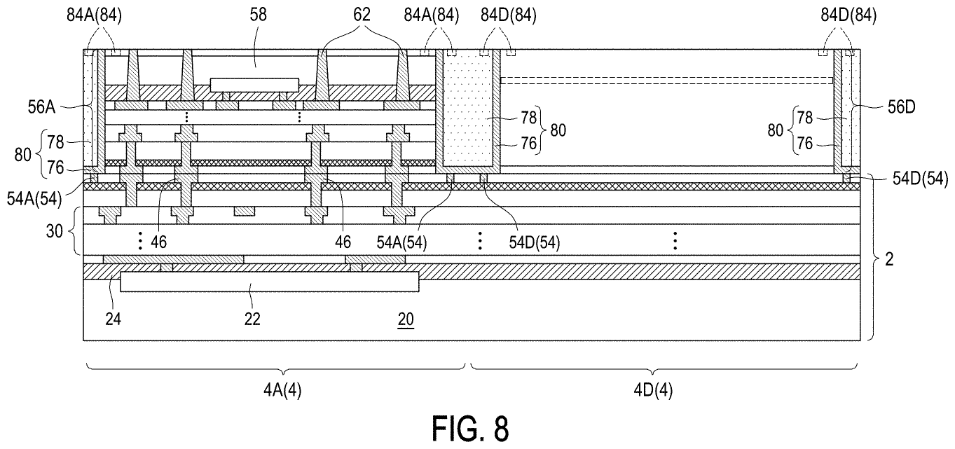

In accordance with some embodiments, more dies are to be stacked over active dies 56A and dummy dies 56D. Accordingly, referring to FIG. 8, alignment marks 84 (including alignment marks 84 84A, and may or may not include alignment marks 84 84D) are formed for the alignment of tier-3 dies. Alignment marks 84A and 84D may be formed on gap-filling dielectric regions 80, and/or may be formed on active dies 56A and dummy dies 56D. The subsequently discussed processes 218, 220, 222, and 224 (FIG. 28) are shown as being dashed to represent that these processes may be or may not be performed.

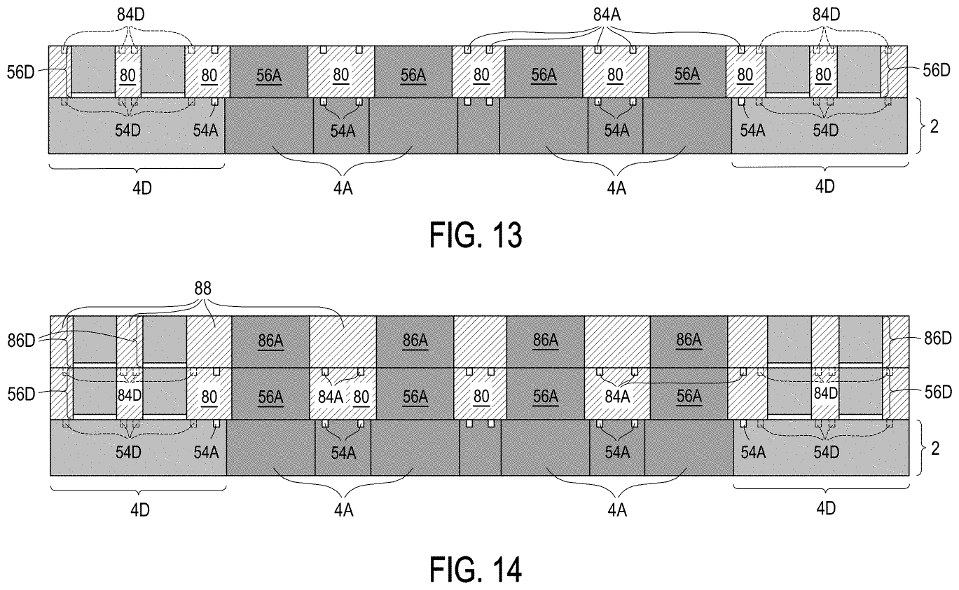

A schematic view of the bonding of tier-3 dies using alignment marks 84 are shown in FIGS. 13 and 14. FIG. 13 illustrates a simplified view of FIG. 8, wherein active dies 56A and dummy dies 56D have been bonded, and alignment marks 84 (including 84A and may or may not include alignment marks 84D) have been formed. In accordance with some embodiments, alignment marks 84A, which are for aligning active dies, are formed first. The respective process is also illustrated as process 218 in the process flow 200 as shown in FIG. 28. Alignment marks 84D (if adopted), which are for aligning dummy dies, are then formed. The respective process is also illustrated as process 220 in the process flow 200 as shown in FIG. 28. In accordance with alternative embodiments, alignment marks 84A and 84D are formed in a same process.

Next, referring to FIG. 14, active dies 86A and dummy dies 86D, which are tier-3 dies, are bonded to the underlying tier-2 dies. In accordance with some embodiments, active dies 86A are bonded first. The respective process is also illustrated as process 222 in the process flow 200 as shown in FIG. 28. Dummy dies 86D are then bonded. The respective process is also illustrated as step 224 in the process flow 200 as shown in FIG. 28. Isolation regions 88 are then formed as gap-fill regions. The formation of isolation regions 88 may be essentially the same as gap-filling dielectric regions 80, and hence are not repeated.

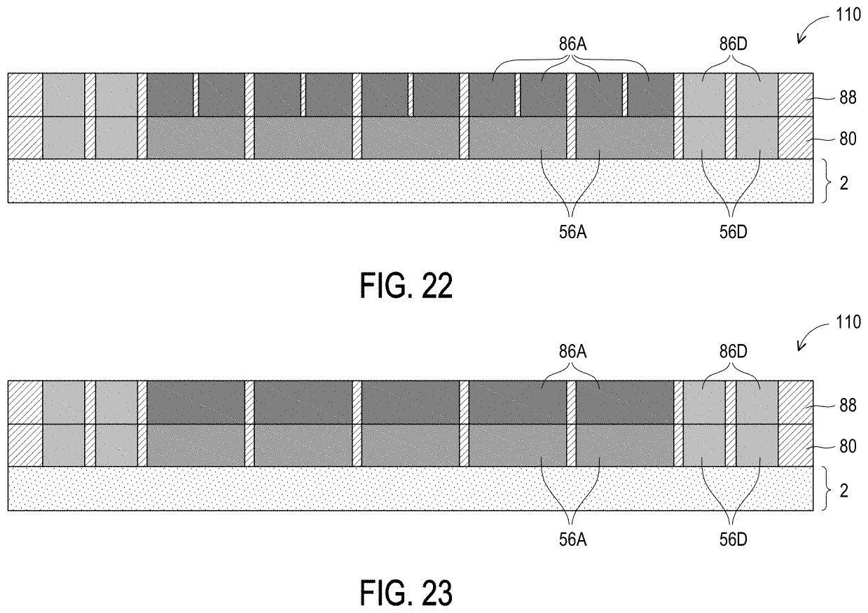

The schematic views of the bonding of upper dies are also shown in FIGS. 22 and 23. FIG. 22 illustrates an embodiment in which each of tier-2 active dies 56A is bonded with two or more tier-3 active dies 86A. FIG. 23 illustrates an embodiment in which each of tier-2 active dies 56A is bonded with one tier-3 active die 86A. There may be, or may not be, more tiers of active dies and dummy dies bonded to tier-3 dies.

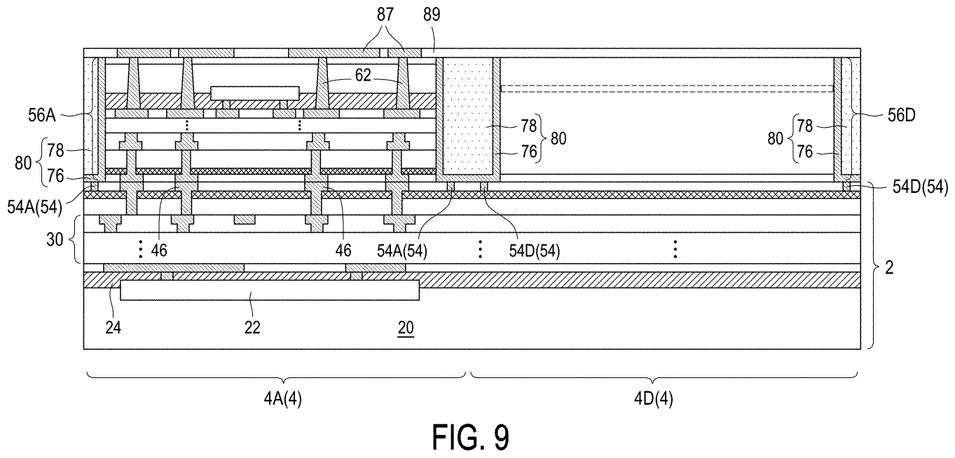

FIGS. 9 through 12 illustrates the processes for forming interconnect structures on the topmost-tier dies (tier-2, tier-3, or higher). The respective process is illustrated as process 226 in the process flow 200 as shown in FIG. 28. Referring to FIG. 9, redistribution lines (RDLs) 87 and dielectric layer 89 are formed. In accordance with some embodiments of the present disclosure, dielectric layer 89 is formed of an oxide such as silicon oxide, a nitride such as silicon nitride, or the like. RDLs 87 may be formed using a damascene process, which includes etching dielectric layer 89 to form openings, depositing a conductive barrier layer into the openings, plating a metallic material such as copper or a copper alloy, and performing a planarization to remove the excess portions of the metallic material and the conductive barrier layer.

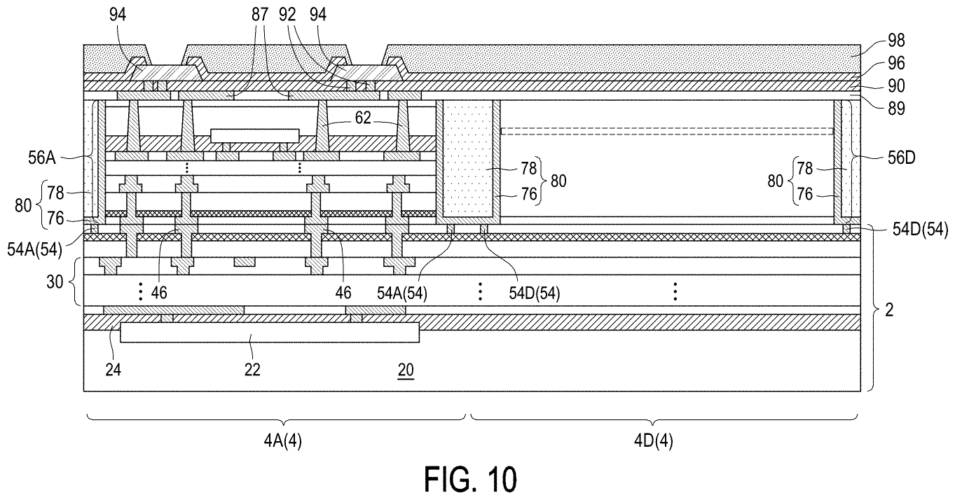

FIG. 10 illustrates the formation of passivation layers, metal pads, and overlying dielectric layers. Passivation layer 90 (sometimes referred to as passivation-1) is formed over dielectric layer 89, and vias 92 are formed in passivation layer 90 to electrically connect to RDLs 87. Metal pads 94 are formed over passivation layer 90, and are electrically coupled to RDLs 87 through vias 92. Metal pads 94 may be aluminum pads or aluminum-copper pads, and other metallic materials may be used.

As also shown in FIG. 10, passivation layer 96 (sometimes referred to as passivation-2) is formed over passivation layer 90. Each of passivation layers 90 and 96 may be a single layer or a composite layer, and may be formed of a non-porous material. In accordance with some embodiments of the present disclosure, one or both of passivation layers 90 and 96 is a composite layer including a silicon oxide layer (not shown separately), and a silicon nitride layer (not shown separately) over the silicon oxide layer. Passivation layers 90 and 96 may also be formed of other non-porous dielectric materials such as Un-doped Silicate Glass (USG), silicon oxynitride, and/or the like.

Next, passivation layer 96 is patterned, so that some portions of passivation layer 96 cover the edge portions of metal pads 94, and some portions of metal pads 94 are exposed through the openings in passivation layer 96. Polymer layer 98 is then dispensed and patterned to expose metal pads 94. Polymer layer 98 may be formed of a polymer such as polyimide, polybenzoxazole (PBO), or the like.

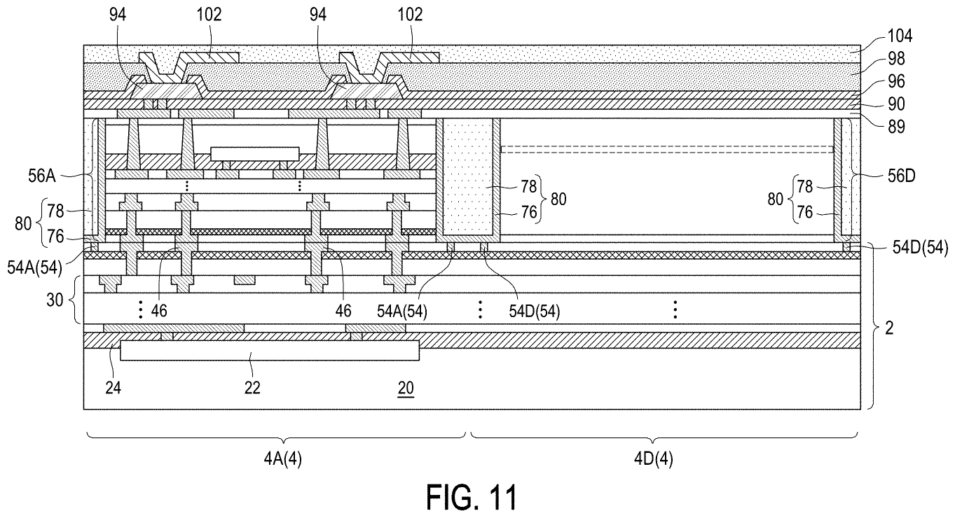

Referring to FIG. 11, Post-Passivation Interconnects (PPI) 102 are formed, which may include forming a metal seed layer and a patterned mask layer (not shown) over the metal seed layer, and plating PPIs 102 in the patterned mask layer. The patterned mask layer and the portions of the metal seed layer overlapped by the patterned mask layer are then removed in etching processes. Polymer layer 104 is then formed, which may be formed of PBO, polyimide, or the like.

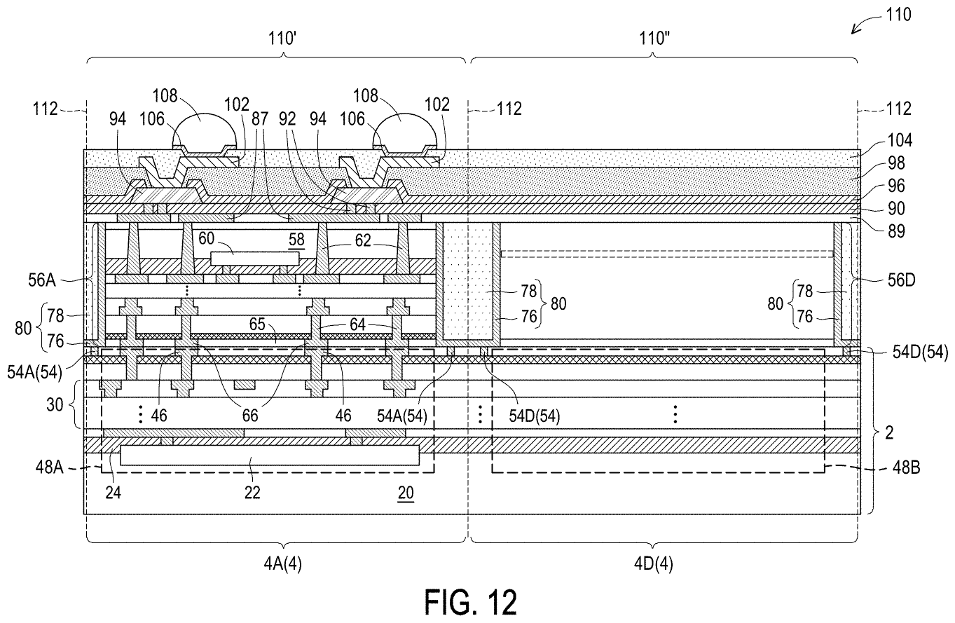

Referring to FIG. 12, Under-Bump Metallurgies (UBMs) 106 are formed, and UBMs 106 extend into polymer layer 104 to connect to PPIs 102. As also shown in FIG. 14, electrical connectors 108 are formed. Electrical connectors 108 may include solder region, metal pillars, and/or the like. Reconstructed wafer 110 is thus formed.

In a subsequent process, a singulation process is performed to saw reconstructed wafer 110 into active packages 110′ and dummy packages 110″. Active packages 110′ may be used for the subsequent packaging process, while dummy packages 110″ are discarded.

In accordance with alternative embodiments, reconstructed wafer 110 is used as a wafer-level package without being sawed. For example, some performance-demanding applications such as Artificial-Intelligence (AI) applications use wafer-level packages. In accordance with these embodiments, the entire reconstructed wafer 110 is used as a package, and a heat sink may be attached to it, for example, attached to wafer 2 through a thermal-interface material. Screws may also penetrate through dielectric gap-fill regions 80/88 and/or dummy dies 56D, and penetrate the heat sink to secure the heat sink to the wafer-level package.

In above-discussed embodiments, the determination of the positions of dummy dies 56D is based on the bonding of active dies, so that the available spaces and the positions of dummy dies 56D are determined from the positions (and reference points) of active dies. In accordance with alternative embodiments, an alternative method for determining the positions of dummy dies is used. Using this method, the dummy dies may be placed closer to each other than the method using reference points to determine the positions of dummy dies. Also, using this embodiment, the time for determining the positions of dummy dies is reduced.

In accordance with these embodiments, the sizes of the dummy dies to be placed on the wafers are first selected, and regardless of the product and the sizes of active dies, the dummy dies of the same size may be used, and the dummy dies of the same size may be used on different products.

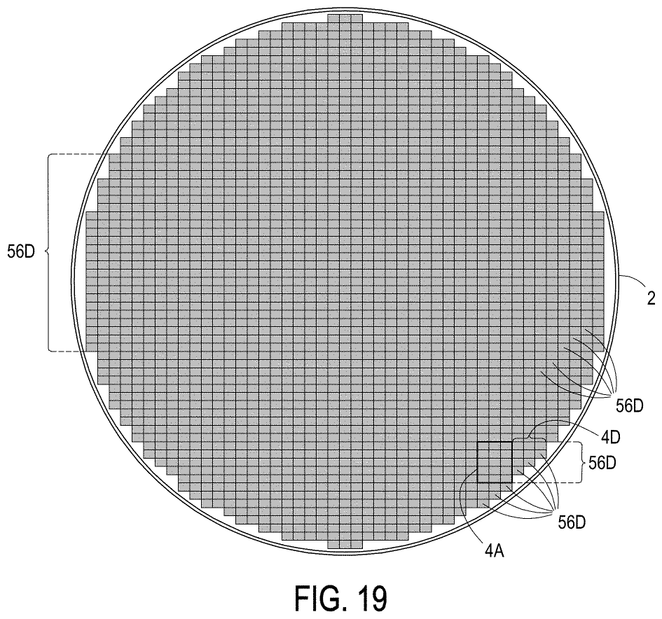

In accordance with these embodiments, an entire wafer is assumed to be able to be placed with dummy dies, and FIG. 19 illustrates the whole-wafer map of dummy dies 56D if they are bonded to the entire wafer 2. Next, the positions of active dies 4A and the corresponding active dies 56A are determined, and the dummy dies 56D that occupy the positions of active dies 56A are removed from the whole-wafer map. Accordingly, a whole-wafer map as shown in FIG. 15 is obtained, wherein the whole-wafer map shows the positions of active dies 4A and 56A and dummy dies 56D.

The active dies 56A may then be bonded to the corresponding positions in the whole-wafer map. Dummy dies 56D may also be placed and bonded to the corresponding positions in the whole-wafer map, as shown in FIG. 15 (also refer to FIG. 5). A brief process flow in accordance with these embodiments are discussed below as an example. First, the processes as shown in FIGS. 1 and 2 are performed. Next, the processes for determining the positions of active dies and dummy dies using the whole-wafer map (as discussed above referring to FIGS. 19 and 15) are performed. Next, both of active alignment marks 54A and dummy alignment marks 54D (FIG. 2) are formed, as shown in FIG. 3, to record the positions of the active alignment marks 54A and dummy alignment marks 54D on the physical wafer 2. The positions of active alignment marks 54A relative to active dies 56A are shown in FIG. 16. The positions of dummy alignment marks 54D relative to dummy dies 56D are shown in FIG. 17. Next, active dies 56A are bonded, as shown in FIG. 4 by using active alignment marks 54A for alignment. Dummy dies 56D are then bonded, as shown in FIG. 5, by using dummy alignment marks 54D for alignment. The processes as shown in FIGS. 6 through 12 are then performed to form packages 110′.

In accordance with some embodiments in which a plurality of tiers of dies are bonded, the active alignment marks and dummy alignment marks may be formed on the bottom wafer 2, and may be formed on upper tiers, so that upper-tier dies may be aligned and bonded.

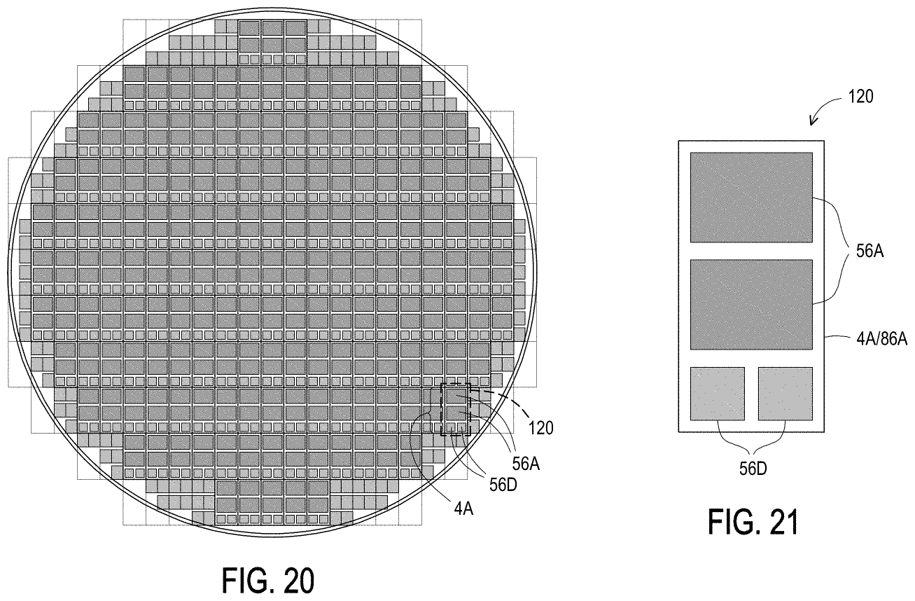

In accordance with some embodiments, dummy dies 56D are inserted to the peripheral regions of wafer 2, and are not inserted to the inner region of wafer 2. Dummy dies 56D are thus bonded with the underlying dummy dies 4D, and are not bonded to active dies 4A. In accordance with alternative embodiments, dummy dies 56D may be inserted to the inner regions of wafer 2, and bonded with active dies 4A. For example, FIG. 20 illustrates wafer 2 and the overlying active dies 56A and dummy dies 56D in accordance with some embodiments. FIG. 21 illustrates an amplified view of the region 120 in FIG. 20, which shows that both of active regions 56A and dummy dies 56D are bonded to the same tier-2 active die 4A and/or the same tier-3 active die 86A.

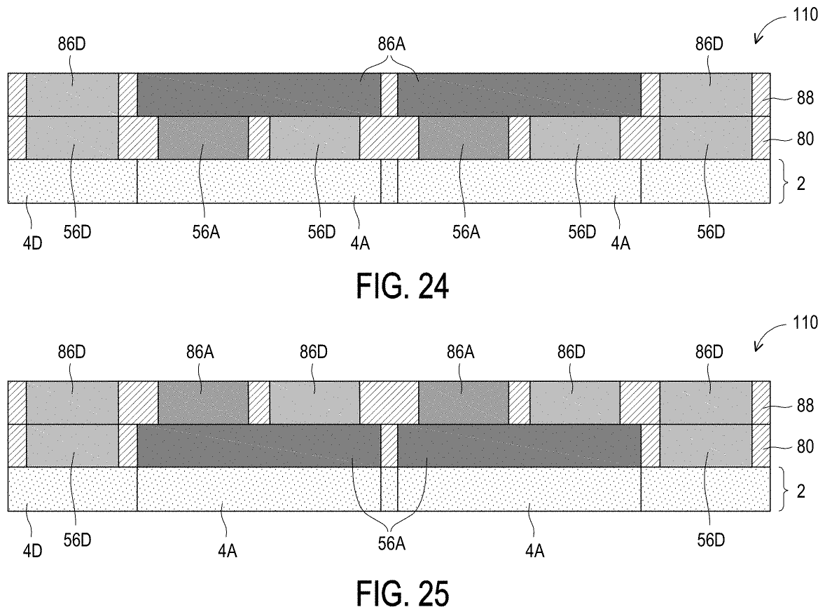

FIG. 24 illustrates the cross-sectional view of a part of reconstructed wafer 110, wherein dummy dies 56D are bonded to both of the underlying active die 4A and the overlying active die 86A. FIG. 25 illustrates the cross-sectional view of a part of reconstructed wafer 110, wherein both of active dies 86A and dummy dies 86D are bonded to the underlying active dies 56A.

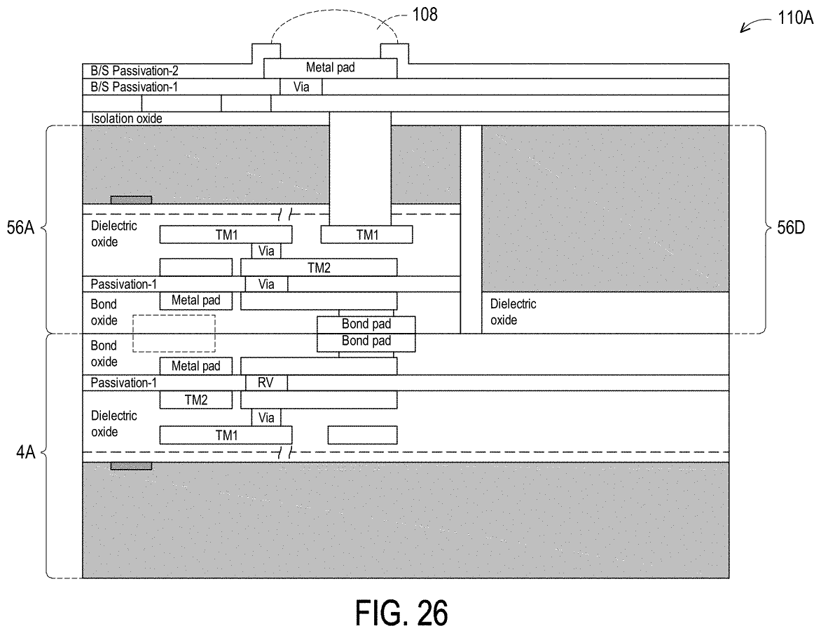

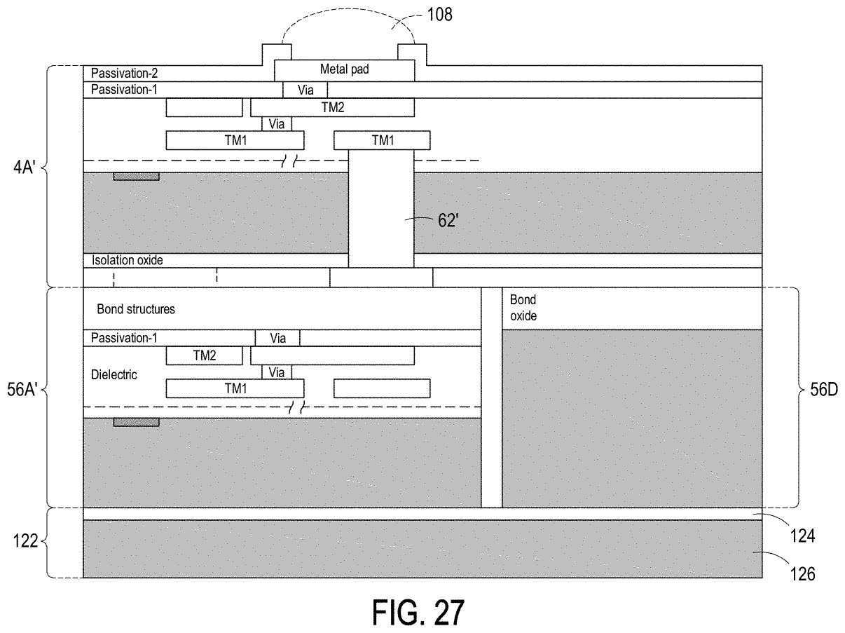

FIG. 26 illustrates a more detailed view of package 110A having redistribution lines and electrical connectors 108 being formed on the top-tier die(s). Dummy die 56D is bonded to active die 4A. The details of active dies 4A and 56A may be found referring to the preceding embodiments. The details of dummy dies 56D may be found referring to the preceding embodiments. In FIGS. 26 and 27, the notations TM1 and TM2 represent metal features.

FIG. 27 illustrates a more detailed view of package 110A having redistribution lines and electrical connectors 108 being formed on the bottom-tier die(s) 4A′ (FIG. 27 is inversed bottom-up). Active die 4A′ may be essentially the same as active die 4A as discussed in preceding embodiments, except through-vias 62′ are formed in active die 4A′. Active die 56A′ and dummy dies 56D are bonded to active die 4A′. Active die 56A′ may be similar to active die 56, except no through-vias are formed therein. Supporting die 122 is bonded to active dies 56A′ and dummy dies 56′, for example, through bond layer 124, with substrate 126 being bonded with bond layer 124. Supporting die 122 may be a blanket die having no integrated circuit devices and metal features therein. Bond layer 124 may be a silicon-containing dielectric layer, and substrate 126 may be a silicon substrate, both being blank layers having no integrated circuit devices and metal features therein.

It is appreciated that although the detailed features in FIGS. 20 through 27 are not shown, the detailed features as shown and discussed referring to FIGS. 1 through 12 may also exist, whenever applicable, and hence the detailed features and their formation processes are not repeated herein.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. In bonding processes such as Chip-on-Wafer bonding processes, rectangular dies in circular wafers and rectangular dies bonded on circular wafers may cause empty areas in the peripheral regions of the wafers. The empty areas are filled by gap-filling materials, which have different CTE values than device dies bonded on the wafer. This will cause the warpage of the resulting reconstructed wafers. It is difficult for production tools to handle warped wafers. In the embodiments of the present disclosure, dummy dies are used to fill the empty areas and to reduce gap-fill ratios, and hence the warpage of the reconstructed wafers is reduced.

In accordance with some embodiments of the present disclosure, a method comprises bonding a first plurality of active dies to a second plurality of active dies in a wafer, wherein the second plurality of active dies are in an inner region of the wafer; and bonding a first plurality of dummy dies to a second plurality of dummy dies in the wafer, wherein the second plurality of dummy dies are in a peripheral region of the wafer, and wherein the peripheral region encircles the inner region. In an embodiment, during the bonding the first plurality of active dies, a stepping window is recorded, and wherein the stepping window comprises a distance between a first active die and a second active die in the first plurality of active dies. In an embodiment, one of the first plurality of dummy dies is bonded using processes comprising determining a first reference point of one of the first plurality of active dies; stepping away from the first reference point by the stepping window to reach a second reference point of a dummy die in the wafer; and bonding the one of the first plurality of dummy dies to the dummy die and to a position offset from the second reference point.

In an embodiment, the first reference point is a center of the one of the first plurality of active dies, and the second reference point is a center of the dummy die. In an embodiment, the first plurality of dummy dies are bonded without using alignment marks for alignment. In an embodiment, the method further comprises generating a full-wafer map comprising dummy dies distributed throughout the full-wafer map; and removing some of the dummy dies from first positions of the full-wafer map, wherein second positions are left for remaining dummy dies, and wherein the first plurality of dummy dies are bonded to the second positions. In an embodiment, the method further comprises forming a first plurality of alignment marks on the wafer, wherein the bonding the first plurality of active dies comprises aligning to the first plurality of alignment marks; and forming a second plurality of alignment marks on the wafer, wherein the bonding the first plurality of dummy dies comprises aligning to the second plurality of alignment marks.

In an embodiment, the wafer comprises a semiconductor substrate continuously extending into the second plurality of active dies and the second plurality of dummy dies. In an embodiment, the wafer comprises a reconstructed wafer, wherein the reconstructed wafer comprises a plurality of gap-filling regions separating the second plurality of active dies and the second plurality of dummy dies from each other. In an embodiment, one of the second plurality of dummy dies is bonded with multiple ones of the first plurality of dummy dies. In an embodiment, a dummy die in the first plurality of dummy dies comprises a silicon-containing dielectric layer and a silicon layer joined to the silicon-containing dielectric layer, wherein the dummy die is bonded to a corresponding one of the second plurality of dummy dies through fusion bonding. In an embodiment, the method further comprises bonding a third plurality of dummy dies on corresponding ones of the first plurality of active dies.

In accordance with some embodiments of the present disclosure, a method comprises forming a wafer having a round top-view shape, the wafer comprising a first plurality of active dies, wherein the first plurality of active dies are in an inner region of the wafer; a first plurality of dummy dies arranged aligning a ring encircling the inner region; bonding a second plurality of active dies to the first plurality of active dies, wherein in the bonding the second plurality of active dies, first reference points of the first plurality of active dies are recorded, and wherein a distance between two neighboring ones of the first plurality of active dies is recorded; stepping away from one of the first reference points by the distance to reach a second reference point; and bonding a second plurality of dummy dies to the first plurality of dummy dies, wherein the bonding the second plurality of dummy dies comprises offsetting from the second reference point to determine a first position; and bonding a first one of the second plurality of dummy dies to the first position.

In an embodiment, the method further comprises offsetting from the second reference point to determine a second position offset from the second reference point; and bonding a second one of the second plurality of dummy dies to the second position. In an embodiment, the first one and the second one of the second plurality of dummy dies are bonded to a same dummy die in the first plurality of dummy dies. In an embodiment, the method further comprises forming a plurality of alignment marks on the wafer, wherein the bonding the second plurality of active dies is performed using the plurality of alignment marks for alignment. In an embodiment, the bonding the second plurality of dummy dies to the first plurality of dummy dies is performed without using alignment marks.

In accordance with some embodiments of the present disclosure, a method comprises forming a wafer comprising a first plurality of active dies and a first plurality of dummy dies; forming a plurality of alignment marks on the wafer; bonding a second plurality of active dies to the first plurality of active dies, with the plurality of alignment marks being used for alignment; determining positions of the first plurality of dummy dies in the wafer based on positions of the plurality of active dies in the wafer; and bonding a second plurality of dummy dies to the first plurality of dummy dies, wherein the second plurality of dummy dies are bonded to the positions. In an embodiment, the determining the positions of the first plurality of dummy dies is performed without using alignment marks. In an embodiment, the first plurality of dummy dies are free from integrated circuits.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first plurality of active dies to a second plurality of active dies in a wafer, wherein the second plurality of active dies are in an inner region of the wafer; and
bonding a first plurality of dummy dies to a second plurality of dummy dies in the wafer, wherein the second plurality of dummy dies are in a peripheral region of the wafer, and wherein the peripheral region encircles the inner region.

2. The method of claim 1, wherein during the bonding the first plurality of active dies, a stepping window is recorded, and wherein the stepping window comprises a distance between a first active die and a second active die in the first plurality of active dies.

3. The method of claim 2, wherein one of the first plurality of dummy dies is bonded using processes comprising:
determining a first reference point of one of the first plurality of active dies;
stepping away from the first reference point by the stepping window to reach a second reference point of a dummy die in the wafer; and
bonding the one of the first plurality of dummy dies to the dummy die and to a position offset from the second reference point.

4. The method of claim 3, wherein the first reference point is a center of the one of the first plurality of active dies, and the second reference point is a center of the dummy die.

5. The method of claim 2, wherein the first plurality of dummy dies are bonded without using alignment marks for alignment.

6. The method of claim 1 first comprising:
generating a full-wafer map comprising dummy dies distributed throughout the full-wafer map; and
removing some of the dummy dies from first positions of the full-wafer map, wherein second positions are left for remaining dummy dies, and wherein the first plurality of dummy dies are bonded to the second positions.

7. The method of claim 6 further comprising:
forming a first plurality of alignment marks on the wafer, wherein the bonding the first plurality of active dies comprises aligning to the first plurality of alignment marks; and
forming a second plurality of alignment marks on the wafer, wherein the bonding the first plurality of dummy dies comprises aligning to the second plurality of alignment marks.

8. The method of claim 1, wherein the wafer comprises a semiconductor substrate continuously extending into the second plurality of active dies and the second plurality of dummy dies.

9. The method of claim 1, wherein the wafer comprises a reconstructed wafer, wherein the reconstructed wafer comprises a plurality of gap-filling regions separating the second plurality of active dies and the second plurality of dummy dies from each other.

10. The method of claim 1, wherein one of the second plurality of dummy dies is bonded with multiple ones of the first plurality of dummy dies.

11. The method of claim 1, wherein a dummy die in the first plurality of dummy dies comprises a silicon-containing dielectric layer and a silicon layer joined to the silicon-containing dielectric layer, wherein the dummy die is bonded to a corresponding one of the second plurality of dummy dies through fusion bonding.

12. The method of claim 1 further comprising:
bonding a third plurality of dummy dies on corresponding ones of the first plurality of active dies.

13. A method comprising:
forming a wafer having a round top-view shape, the wafer comprising:
a first plurality of active dies, wherein the first plurality of active dies are in an inner region of the wafer;
a first plurality of dummy dies arranged aligning a ring encircling the inner region;
bonding a second plurality of active dies to the first plurality of active dies, wherein in the bonding the second plurality of active dies, first reference points of the first plurality of active dies are recorded, and wherein a distance between two neighboring ones of the first plurality of active dies is recorded;
stepping away from one of the first reference points by the distance to reach a second reference point; and
bonding a second plurality of dummy dies to the first plurality of dummy dies, wherein the bonding the second plurality of dummy dies comprises:
offsetting from the second reference point to determine a first position; and
bonding a first one of the second plurality of dummy dies to the first position.

14. The method of claim 13 further comprising:
offsetting from the second reference point to determine a second position offset from the second reference point; and
bonding a second one of the second plurality of dummy dies to the second position.

15. The method of claim 14, wherein the first one and the second one of the second plurality of dummy dies are bonded to a same dummy die in the first plurality of dummy dies.

16. The method of claim 13 further comprising forming a plurality of alignment marks on the wafer, wherein the bonding the second plurality of active dies is performed using the plurality of alignment marks for alignment.

17. The method of claim 16, wherein the bonding the second plurality of dummy dies to the first plurality of dummy dies is performed without using alignment marks.

18. A method comprising:
forming a wafer comprising a first plurality of active dies and a first plurality of dummy dies;
forming a plurality of alignment marks on the wafer;
bonding a second plurality of active dies to the first plurality of active dies, with the plurality of alignment marks being used for alignment;
determining positions of the first plurality of dummy dies in the wafer based on positions of the plurality of active dies in the wafer; and
bonding a second plurality of dummy dies to the first plurality of dummy dies, wherein the second plurality of dummy dies are bonded to the positions.

19. The method of claim 18, wherein the determining the positions of the first plurality of dummy dies is performed without using alignment marks.

20. The method of claim 18, wherein the first plurality of dummy dies are free from integrated circuits.
